(19) United States
(12) Patent Application Publication
(10) Pub. No.: US 2011/0186106 A1
(43) Pub. Date: Aug. 4, 2011

(54) HYBRID CONCENTRATOR SOLAR ENERGY DEVICE

(75) Inventors: Reginald Parker, Arlington, VA (US); Frederick J. Foreman, Haymarket, VA (US)

(73) Assignee: 510NANO INC., Washington, DC (US)

(21) Appl. No.: 13/019,021

(22) Filed: Feb. 1, 2011

Related U.S. Application Data
(60) Provisional application No. 61/301,030, filed on Feb. 3, 2010.

(51) Int. Cl. H01L 31/058; H01L 31/052

(52) U.S. Cl. 136/246; 136/248

(57) ABSTRACT

An apparatus for generating electricity with the ability to distill a liquid and/or expand a working fluid and/or produce mechanical energy and/or produce thermal energy and/or produce chemical energy through separately utilizing light in the infrared (IR) region and light within the visible and ultraviolet (UV) regions. The apparatus uses polychromatic light concentration and multiplication, light collimation, spectral separation, photoelectric generation through conversion of visible light, and useful conversion of infrared light into applications to generate a distilled liquid, expand a working fluid, produce mechanical energy, produce thermal energy, produce chemical energy and/or generate electricity. Non-reflected radiant energy may be used to operate a suitable photovoltaic cell or stack of cells. In alternative embodiments, the spectral separator may reflect most radiant energy incident upon it to one or more photovoltaic cells and pass infrared to an accumulator for use as heat energy to generate mechanical or chemical energy or generate further electrical energy.

This application claims the benefit of priority to U.S. Provisional Application Ser. No. 61/301,030 filed Feb. 3, 2010 by the same inventors, the entire subject matter of which is incorporated by reference herein in its entirety.

### TECHNICAL FIELD

This invention generally relates to the technical field of solar energy conversion apparatus and, more particularly, to an apparatus for efficiently using solar radiation for generating electricity, distilling liquid, expanding working fluid, generating mechanical energy, reacting chemicals and/or producing thermal energy.

### BACKGROUND

The following discussion of the solar energy arts should not be construed as an admission that the subject matter of the discussion is known to others.

Bright sunlight is known to provide an irradiance of just over 1 kilowatt per square meter at sea level. Of this energy, 527 watts power is infrared radiation; 445 watts is visible light; and 32 watts is ultraviolet radiation. The visible light energy is received primarily as panchromatic light at approximately equivalent level across the visible light spectrum. There is little energy received as heat in the visible spectra. However, infrared energy is received within as infrared radiation and as heat radiation. Typically, solar energy panels receive sun energy and pass the energy to photovoltaic cells which convert approximately 18% of the received energy into electric energy for mono-crystalline silicon based solar panels which electric energy may be used in the world's power grid.

Efficient and strategic concentration, separation, collection and use of radiant energy is useful in a number of applications. Radiant energy is of particular value for devices that convert solar energy to various energy forms and is useful in the delivery of various distilled liquids with a boiling point up to 740° F. or higher. Concentrator technology can multiply the sun's energy at two times the sun's energy or lower and as much as 100 times the sun's energy or more. Concentrator technology is achieved by focusing the sun's power onto a smaller platform. As an example, a 10 inch by 10 inch Fresnel lens can focus the sun's energy onto a 1 inch by 1 inch surface. In doing so, the surface will experience the power of 100 times the power of the sun (or 100 suns). Other lens and concentrating systems are known and may be considered similar devices such as magnifying lens systems comprising multiple lenses at predetermined focal lengths from one another and the like known by their power of magnification.

Applications for radiation concentrator technology may be for concentrated photovoltaic technology (CPV) or for concentrated solar thermal (CST) technology. CPV uses the concentrated light onto a solar cell, for example, a known photovoltaic cell. An increase in solar radiation increases the production of photocurrent by the cell; however, there is a concurrent decrease in overall power due to the addition of heat found in IR energy which may be lost in the light to electric conversion process. CST, on the other hand, for example, may heat a working fluid which either directly or indirectly drives a turbine producing electricity and/or utility scale steam. The majority of the heating of the working fluid is derived from the IR portion of the spectrum. Thus, CPV and CST in combination are promising technologies requiring further development; however, IR light reduces the efficiency of CPV, and visible light is ineffectual in CST.

Large-scale light concentrators for obtaining solar energy typically include a set of opposed, curved minors, with a Cassegrain arrangement, as an optical system for concentrating light onto a receiver that is positioned at a focal point. A few examples employing the Cassegrain model are U.S. Pat. No. 5,979,438 and U.S. Pat. No. 5,005,958 incorporated by reference herein in their entirety. U.S. Pat. No. 6,530,369 describes a solar concentration system comprising a system of first reflectors for concentrating toward a second reflector for focusing light at a solar conversion device. U.S. Pat. No. 7,669,593 discloses a concentration tower having a plurality of reflectors for directing radiant energy at a reflector mounted at the top of a tower.

A more recent development may provide a more compact collection apparatus, planar concentrators. Planar concentrators similarly employ primary and secondary curved minors with a Cassegrain arrangement, separated by a dielectric optical material, for providing high light flux concentration.

Other examples of light concentrators include the use of Fresnel lens as an optical system for concentrating light onto a receiver that is positioned at a focal point. A few examples employing the Fresnel model are U.S. Pat. No. 4,069,812, U.S. Pat. No. 4,088,120 and U.S. Pat. No. 6,399,874.

Some types of solar energy systems operate by converting light energy to heat. In various types of flat plate collectors and solar concentrators, concentrated sunlight heats a fluid traveling through the solar cell to high temperatures for power generation. An alternative type of solar conversion mechanism, more adaptable for use in thin panels and more compact devices, may use photovoltaic (PV) materials to convert sunlight directly into electrical energy.

As is well known, sunlight is highly polychromatic. Sunlight contains broadly distributed spectral content at all frequencies, ranging, for example, from ultraviolet (UV), through visible, and infrared (IR) wavelengths, each wavelength having an associated energy level, typically expressed in terms of electron-volts (eV). Due to differing band-gap characteristics between materials, the response of any one particular photovoltaic material depends upon the incident wavelength. Photons having an energy level below the band gap of a material slip through the material. For example, it is to be noted that red light photons (nominally around 1.9 eV) are not absorbed by high band-gap semiconductors and energy from violet light photons (nominally around 3 eV) is wasted as heat in a low band-gap semiconductor.

One strategy for obtaining higher efficiencies from photovoltaic materials is to form a stacked photovoltaic cell, also sometimes termed a multi-function photovoltaic device. These devices are formed by stacking multiple photovoltaic cells on top of each other. With such a design, each successive photovoltaic cell in the stack, with respect to the incident light source, has a lower band-gap energy due to the depth of the stack. In a simple stacked photovoltaic device, for example, an upper photovoltaic cell, consisting of gallium arsenide (GaAs), captures the higher energy of blue light. A second cell in the stack, of gallium antimonide (GaSb), converts the lower energy infrared light into electricity. One example of a stacked photovoltaic device is given in U.S. Pat. No. 6,835,888 entitled “Stacked Photovoltaic Device” to Sano et al., incorporated by reference herein in its entirety.

While stacked photovoltaic devices can provide some measure of improvement in overall efficiency, these multi-layered devices can be costly to fabricate. There can also be restrictions on the types of materials that can be stacked together on top of each other, making it difficult for such an approach to prove economical for a broad range of applications. Another approach is to separate the light according to wavelength into two or more different spectral portions, and to concentrate each portion onto an appropriate photovoltaic receiver device, with two or more photovoltaic receivers arranged side by side. With this approach, photovoltaic device fabrication is simpler and less costly, and a wider variety of semiconductors can be considered for use. This type of solution requires supporting optics for both separating light into suitable spectral components and concentrating each spectral component onto its corresponding photovoltaic surface and, in some cases, collimating diffuse light.

One proposed solution for simultaneously separating and concentrating light at sufficient intensity is described in a paper entitled “New Cassegrainian PV Module using Dichroic Secondary and Multijunction Solar Cells” presented at an International Conference on Solar Concentration for the Generation of Electricity or Hydrogen in May, 2005 by L. Fraas, J. Avery, H. Huang, and E. Shifman (hereinafter, Fraas et al). In the module described, a curved primary mirror collects light and directs this light toward a dichroic hyperbolic secondary mirror, near the focal plane of the primary mirror. IR light is concentrated at a first photovoltaic receiver near the focal point of the primary minor. The secondary minor redirects near-visible light to a second photovoltaic receiver positioned near a vertex of the primary mirror. In this way, each photovoltaic receiver obtains the light energy for which it is optimized, increasing the overall efficiency of the solar cell system. A further dichroic system incorporating a Cassegrain solution is described by U.S. Pat. No. 7,741,557 which discusses the separation of first and second spectral bands for transmission to first and second planar surfaces. The light of the first and second spectral bands are received at first and second photovoltaic cells.

While the approach described by Fraas et al. advantageously provides spectral separation and concentrates light using the same set of optical components, there are some significant limitations to the solution that it presents. A first problem relates to the overall losses due to obstruction, as were noted earlier. As another problem, the apparatus described by Fraas et al. has a limited field of view of the sky because it has a high concentration in each axis due to its rotational symmetry. Yet another drawback relates to the wide bandwidths of visible light provided to a single photovoltaic receiver. With many types of photovoltaic materials commonly used for visible light, an appreciable amount of the light energy would still be wasted using such an approach, possibly causing excessive heat. Yet another drawback is its inability to effectively use diffuse light to generate electricity as some diffuse light is rejected due to its angle of entry.

Dichroic surfaces are used for the hyperbolic minor in the solution proposed by, for example, Fraas et al., to provide spectral separation of light using interference effects obtained from coatings formed from multiple overlaid layers having different indices of refraction and other characteristics. In operation, dichroic coatings may reflect and transmit light as a function of incident angle and wavelength. As the incident angle varies, the wavelength of light that is transmitted or reflected by a dichroic surface also changes. Where a dichroic coating is used with incident light at angles beyond about +/−20 degrees from normal, undesirable spectral effects can occur, so that spectral separation of light, due to wavelength differences, is compromised at such higher angles.

There have been a number of light collector solutions employing dichroic surfaces for spectral splitting. For example, in an article entitled “Spectral Beam Splitting Technology for Increased Conversion Efficiency in Solar Concentrating Systems: A Review”, available online at www.sciencedirect.com, authors A. G. Imenes, and D. R. Mills provide a survey of solar collection systems, including some using dichroic surfaces. For example, the description of a tower reflector (FIG. 24 in the Imenes and Mills article) shows one proposed solution that employs a curved dichroic beamsplitter as part of the optics collection system. High incident angles of some portion of the light on this surface could render such a solution as less than satisfactory with respect to light efficiency. Similarly, U.S. Pat. No. 4,700,013 entitled “Hybrid Solar Energy Generating System” to Soule describes the use of a dichroic surface as a selective heat mirror, incorporated by reference in its entirety.

There are inherent problems with dichroic surface shape and placement for light focused from a parabolic minor. A flat dichroic surface positioned near the focal region of a parabolic reflector would exhibit poor separation performance for many designs, constraining the dimensions of a light collection system. A properly curved dichroic surface, such as a hyperbolic curved surface, can be positioned at or near the focal region, but may obstruct some portion of the available light, as noted earlier.

Conventional approaches for light concentration have been primarily directed to rotationally symmetrical optical systems using large-scale components. However, this approach may not yield satisfactory solutions for smaller solar panel devices. There exists a need for an anamorphic light concentrator that can be formed on a transparent body and fabricated in a range of sizes, where the light concentrator design allows it to be extended in a direction orthogonal to the direction of its highest optical power, whether extended linearly or extended along a curve.

Against obstacles such as poor dichroic surface response, conventional approaches have provided only a limited number of solutions for achieving, at the same time, both good spectral separation and efficient light flux concentration of each spectral component. The Fresnel model may be used to remove those issues. A flat dichroic surface may be used to separate light to allow for efficient separation. Use of collimation will provide more efficient use of technologies such as Fresnel lens and flat dichroic surfaces. Further use of solar thermal applications allow for generation of thermal, mechanical, chemical and/or electrical energy, as well as expansion of a working fluid, storage of energy through production of Hydrogen, remediation of polluting streams, and/or generation of potable water.

A problem faced, for example, by satellites, is the focusing of radiant energy when the satellite is forever moving in relation to the sun. U.S. Pat. No. 6,557,804 suggests using synchronized motors to continuously point a solar panel at the sun as the satellite moves through the sky.

A heat accumulator may be used with solar panels to collect, preserve and transfer heat. Known heat accumulators are described, for example, by U.S. Pat. Nos. 3,845,625; 4,434,785; and 4,714,821. For example, the electric heating coils 19 of the '821 patent may be replaced with infrared energy absorbent material.

These prior art technologies suggest that there is an opportunity to improve the efficiency of solar to electrical energy and other form of energy conversion from, for example, typical solar energy conversion efficiency rates of approximately 18% for mono-crystalline silicon solar cells by a factor of at least two.

### SUMMARY OF THE EMBODIMENTS

It is an object of embodiments of the present invention to advance the art of light collimation and collection as well as spectral separation for energy collection. With this object in mind, the present invention provides a number of embodiments of apparatus for obtaining radiant energy from a polychromatic radiant energy source, the apparatus comprising: a) one or more collimators, b) one or more concentrators, c) at least one spectral separator, d) at least one photovoltaic device, and e) at least one IR collector. The IR collector or accumulator can be an IR photovoltaic device, a heat accumulator and/or a motor that uses an expanding working fluid (e.g. a steam generator, a hydraulic motor, or an air turbine) and/or a reacting medium (e.g. high temperature electrolysis, endothermic reactions or polymerizations). Additionally, use of a steam generator allows for generation of potable water and utility grade steam.

It is an aspect of the embodiments that an apparatus provides concentration of light with its subsequent spectral separation into at least two spectral bands, and energy conversion onto two separate collectors. One collector directly produces electrical energy through conversion of visible and UV light bands into electricity, and the other collector is able to convert IR light bands into various energy forms.

It is another aspect of the embodiments that an apparatus produce potable water and utility grade steam.

It is a further aspect that embodiments of the apparatus provide an efficient mechanism for separating and concentrating radiant energy onto a photoreceiver.

Additionally, it is an aspect of the embodiments that associated apparatus reduces losses from obstruction, common to systems using the Cassegrain model.

According to one embodiment, an optional collimator is used to collect and channel received diffuse radiant energy to a first converging Fresnel lens. The collimator may collect light energy, for example, as the sun crosses the sky. If the Fresnel lens is used alone without a collimator, the Fresnel lens and other elements described below may be moved so as to follow the path of the sun across the sky by a programmed motor for simultaneous rotation and tilt following the solar calendar. The converging Fresnel lens, in turn, passes incident radiant energy, for example, to a diverging Fresnel lens which passes energy to a spectrum separator, for example, a dichroic lens. The dichroic lens may reflect the infrared energy incident on the dichroic lens via a further converging Fresnel lens to an accumulator which, for example, may collect heat energy and transfer the energy for use as chemical energy or mechanical energy. Meanwhile, the spectrum separator may pass all other bands of radiant energy via yet another Fresnel lens to a photovoltaic cell for generation of electrical energy. In a further embodiment, the collimator, separator and Fresnel lens systems may be formed as an array for reflecting all incident infrared heat energy to a single, central accumulator. In this manner, up to 60% energy efficiency is achieved between incident radiant energy and useful energy output.

According to another embodiment, an apparatus may transform larger chemical compounds into the molecular or elemental form. For example, the apparatus may be used to transform water into molecular Hydrogen and molecular oxygen or hydrocarbon outputs into molecular hydrogen and molecular carbon. In doing so, remediation of polluting streams can be achieved, as well as production of molecular Hydrogen as a means of storing potential energy.

According to yet another embodiment, the use of one or more collimators can be used before or after a range of one or more concentrator technologies can be used to form an apparatus for the generation of various forms of useful energy.

These and other features of the embodiments will be described with reference to the drawings of which the following is a brief description.

### BRIEF DESCRIPTION OF THE DRAWINGS

FIG. 1 provides an overall system diagram showing a first embodiment of a radiant energy concentrator system including a spectral separator.

FIG. 2 provides a enlarged diagram of light devices including the spectral separator of FIG. 1.

FIG. 3(A)-(B) provide alternative embodiments of light devices including a collimator and Fresnel lens systems for separating received radiant energy into bands for electrical, chemical and mechanical energy generation.

FIG. 4(A) shows a perspective view of an exemplary array of 2 by 2 Fresnel lens systems for delivering a first visible light band to respective photovoltaic cells and dichroic lenses for transmitting infrared light as heat to a central collector column of heat for delivery to various mechanical and chemical systems as will be further discussed herein; FIG. 4(B) shows a side view of the embodiment of FIG. 4(A) and FIG. 4(C) shows a bottom view of the embodiment of FIG. 4(A).

### DESCRIPTION OF ILLUSTRATIVE EMBODIMENTS

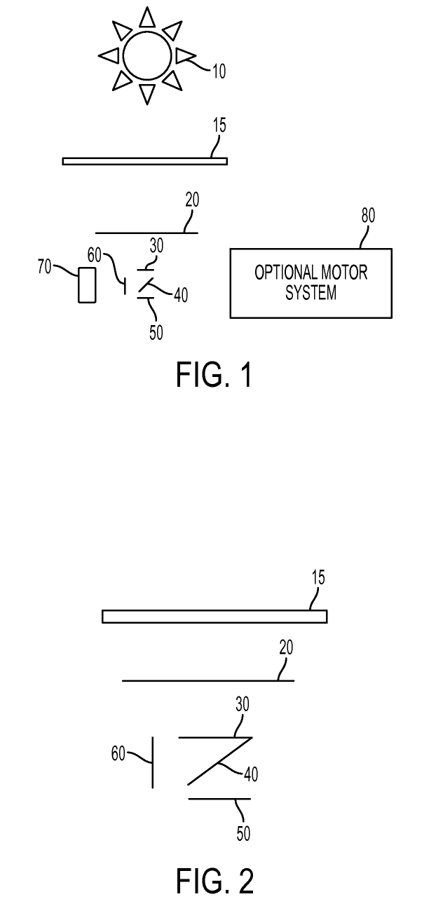

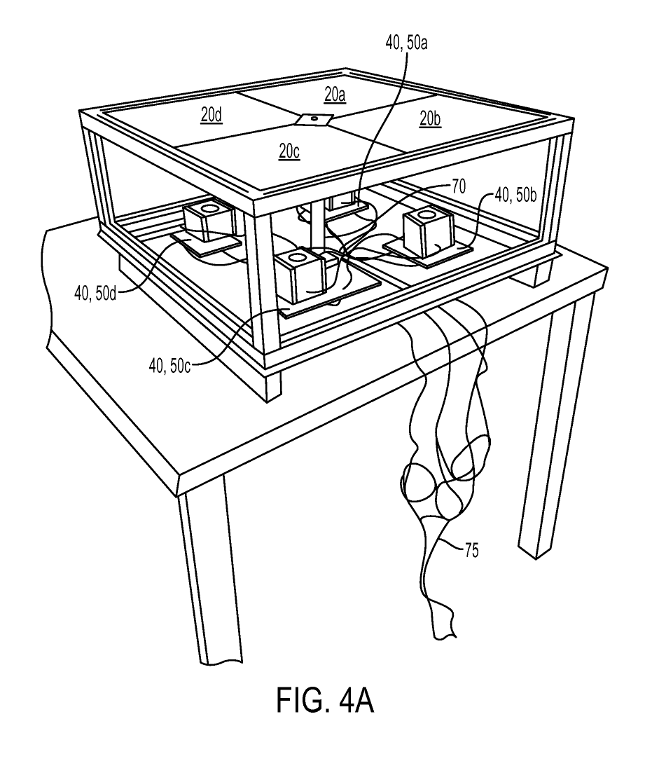

Similar reference characters will be used with reference to FIGS. 1-4 to represent similar elements. Electromagnetic radiation 10, for example, radiant energy from the sun may transmit light onto a collimator 15 first or directly on to a Fresnel lens 20. Collimator 15 collects and multiplies energy incident on it by a predetermined factor. By electromagnetic radiation 10, for example, radiant energy from the sun is used herein to comprise polychromatic visible light, infrared, ultraviolet and all other energy received at the earth's surface from the sun. A suitable collimator 15, for example, may be one obtained from Remote Light Inc. of Colorado, which may multiply incident radiation by a factor of one hundred. In other words, in alternative embodiments, collimator 15 may first collect, receive and multiply radiant energy from, for example, sun source 10, (or alternatively, Fresnel lens 20 may first receive radiant energy from sun source 10), as will be explained further with reference to FIG. 3. Each of the collimator 15 and Fresnel lens devices may be a multiplier of incident energy.

The collimator 15, according to FIGS. 1, 2 and 3 may multiply the received electromagnetic radiation 10 by a predetermined factor. The collimator 15 acts as a funnel or light pipe for capturing light received from various directions. According to FIGS. 1 and 1, collimator 15 collects and concentrates radiant energy for reception at Fresnel lens 20, for example, on the order of a factor of one hundred times. The approximate distance between collimator 15 and Fresnel lens 20 is on the order of 2 to 5 cm in one embodiment, depending on the collimator 15 and Fresnel lens characteristics and parameters.

Furthermore, for example, a converging Fresnel lens 20 may multiply the electromagnetic radiation it receives directly from the sun source 10 or from the collimator 15 by a further predetermined factor. In one example, if collimator 15 multiplies by one hundred and converging Fresnel lens 20 by seven then, incident radiant energy is multiplied by a total factor of seven hundred. In an alternative embodiment, the collimator 15 may be eliminated or replaced by a second Fresnel lens.

When a Fresnel lens is used as a concentrator, due to the light focusing characteristic of the Fresnel lens, a Fresnel lens is desirably used in conjunction with a motor system 80 or a plurality of light reflectors, not shown, for collecting and delivering the light to Fresnel lens 20 so that it may be further delivered without loss of radiant energy to system 30, 40, 50, 60, 70. The converging Fresnel lens 20, for example, may transmit light it receives onto a diverging Fresnel lens 30.

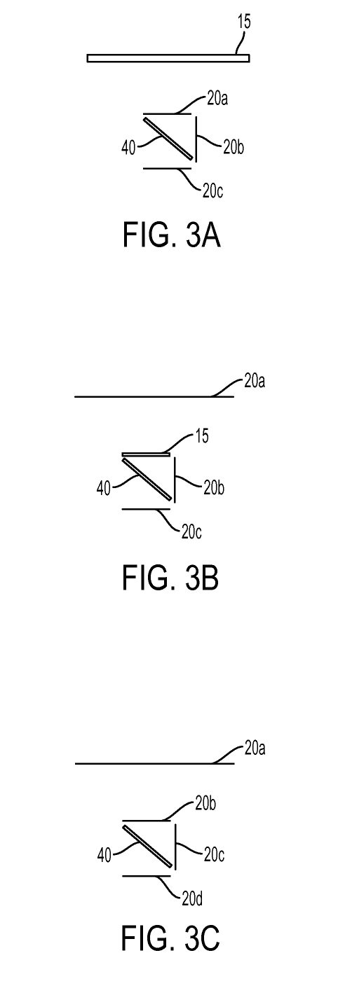

Converging Fresnel lens 20 and all elements shown below the Fresnel lens 20 in FIGS. 1 and 2 may be moved as the sun moves across the sky in the various seasons of the year via a motor system 80 controlled according to a sun calendar. A processor and associated software for motor control are not shown. The motor is more conveniently used if the converging Fresnel lens 20 is used without a collimator 10. A similar motor system is known, for example, from the field of telecommunications transmission and reception, for example, satellite tracking motor control systems with a difference being that the present system 80 may track the travel of the sun 10 or other source of electromagnetic radiation, if it is a moving source, for example, tracking the sun as it travels across the sky.

As the light exits the diverging Fresnel lens 30, the light may be further collimated by a collimator not shown in FIG. 1 or 2, but see FIG. 3B. Visible and invisible light (for example, ultraviolet) exiting the Fresnel lens 30 of FIG. 1 or 2 may be transmitted through a spectrum separator, for example, a dichroic lens 40 (hot) (or reflected by (cool) dichroic lens 40) and onto a solar photovoltaic cell 50 which produces electrical energy directly. The depicted spectrum separator 40 is shown at an angle of approximately 45°. In alternative embodiments, the angle may be between 20° and 80° depending on, for example, the desired location of a receiver such as a photovoltaic cell 50 or other energy accumulator 70 (for example, for accumulating heat energy). Accumulator 70 may, in one embodiment, comprise a steam or stirling engine available from Edmund Scientific for generating an expanding liquid or gas. In another embodiment, accumulator 70 may be a conventional heat accumulator known in the art for receiving and accumulating infrared energy.

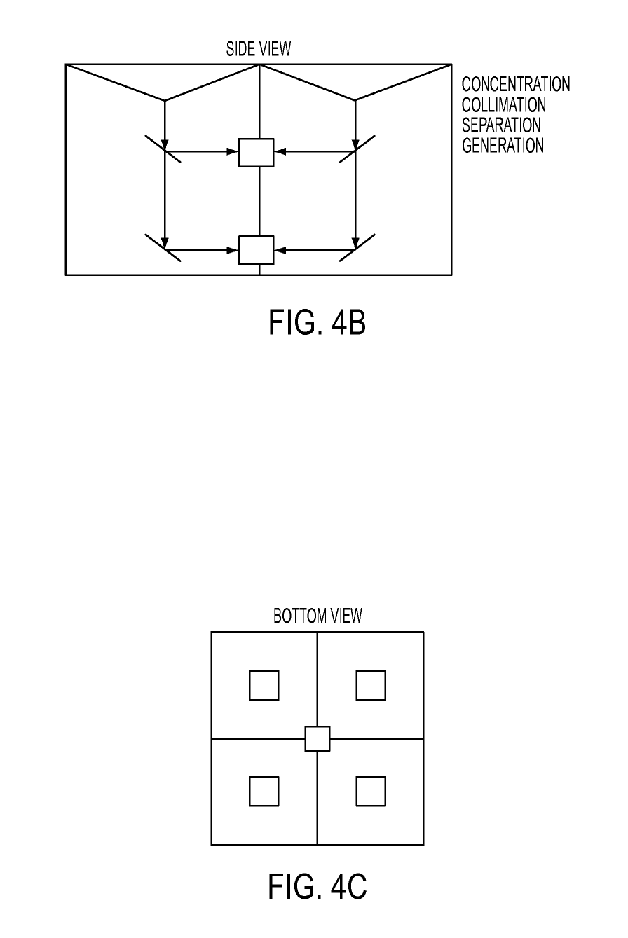

A plurality of stacked hot or cool spectrum separators, for example, dichroic lenses, 40 may receive light and transmit or reflect the light at different spectral bands to different photovoltaic cells 50 or accumulators 70 operable at different spectral bands at different receiving locations. On the other hand, infrared light may be reflected from the dichroic lens 40 either onto an accumulator 70, a further collimator, not shown, or is focused through an IR Fresnel lens 60 onto an accumulator 70. Moreover, in one embodiment, an array of 2×2 or other array of Fresnel lenses (FIG. 4) and spectrum separators may direct infrared energy to a single, central accumulator 70. Thus, the depicted IR Fresnel lens 60 may be optional or useful to increase the overall electrical efficiency or for mechanical or chemical energy generation. The accumulator 70 then may, for example, either distill liquid, expand a working fluid, produce mechanical energy, generate thermal energy, convert hazardous waste into fuel and/or generate electrical energy.

FIGS. 3(A) to (C) show a plurality of embodiments utilizing collimator 15 and Fresnel lenses 20 in various combinations with hot or cold separators 40. For example, FIG. 3A shows an embodiment where collimator 15 multiplies and collects radiant energy and transmits received, collected radiant energy to Fresnel lens 20a which focuses the radiant energy on separator 40 which may be hot or cold. If separator 40 is hot, it passes infrared energy to be focused by further Fresnel lens 20c on to an accumulator 70 not shown below. Separator 40 reflects visible light toward Fresnel lens 20b for delivery to a photovoltaic cell 50 not shown. If cold, the infrared energy is reflected by separator 40 and reflected toward Fresnel lens 20b at the right for focusing on an accumulator 70 not shown. Visible light is passed by cold separator 40 to a Fresnel lens 20c to a photovoltaic cell 50 below (not shown).

FIG. 3B may be similarly explained to one of ordinary skill understanding that FIG. 3B comprises Fresnel lens 20a as a first multiplier for transmitting radiant energy it receives to collimator 15. Collimator 15 pipes the received radiant energy to hot or cold separator 40, for example, a suitable dichroic filter. If separator 40 is hot, it passes infrared energy to be focused by further Fresnel lens 20c on to an accumulator 70 not shown below. Separator 40 reflects visible light toward Fresnel lens 20b for delivery to a photovoltaic cell 50 not shown. If cold, the infrared energy is reflected by separator 40 and reflected toward Fresnel lens 20b at the right for focusing on an accumulator 70 not shown. Visible light is passed by cold separator 40 to a Fresnel lens 20c to a photovoltaic cell 50 below (not shown).

FIG. 3C may be similarly explained to one of ordinary skill understanding that FIG. 3C comprises first Fresnel lens 20a as a first multiplier for transmitting radiant energy it receives to second Fresnel lens 20b as a second multiplier. Second Fresnel lens 20b transmits the received radiant energy to hot or cold separator 40, for example, a suitable dichroic filter. If separator 40 is hot, it passes infrared energy to be focused by further Fresnel lens 20d on to an accumulator 70 not shown below. Separator 40 reflects visible light toward Fresnel lens 20c for delivery to a photovoltaic cell 50 not shown. If cold, the infrared energy is reflected by separator 40 and reflected toward Fresnel lens 20c at the right for focusing on an accumulator 70 not shown. Visible light is passed by cold separator 40 to a Fresnel lens 20d to a photovoltaic cell 50 below (not shown).

FIG. 4(A) is a perspective view drawing showing a Fresnel lens system in the form of a 2 by 2 array for multiplying light and delivering the infrared portion of the spectrum to a single accumulator 70 at the center of a system of a 2 by 2 array of separators 40. FIG. 4(B) provides a side view of the system of FIG. 4(A) showing the steps of concentration, collimation separation and energy generation (where the concentration and collimation may be reversed). FIG. 4(B) may show a photovoltaic cell as a white box and an energy accumulator as a black box where only the black box is seen in bottom view FIG. 4(C). By using a collimator 15 (not shown) to collect diffuse radiant energy for each Fresnel lens 20 of such a system as depicted in FIG. 4(A), the overall efficiency of conversion of incident radiant energy to, for example, electric energy may be increased from a typical 18% to an efficiency in excess of 40% and, in one embodiment, in excess of 60%. Converging Fresnel lenses 20a, 20b, 20c and 20d are shown receiving incident radiant energy and delivering and multiplying received energy to a system as seen in FIG. 2 comprising, for example, at least a spectrum separator 40 for reflecting IR and a photovoltaic cell 50 for generating electricity. An accumulator 70, shaped as a central cylindrical column, receives infrared heat energy which may be converted to chemical or electrical or mechanical energy. Each photovoltaic cell has output leads 75 which may be collected and passed through an aperture in the planar base surface of the system.

One or a plurality of embodiments of a system such as may be seen in FIG. 4(A) through FIG. 4(C) may be mounted, for example, on the roof of a manufacturing facility with hazardous waste as an output. The visible spectrum may be used for generating electricity for running the plant and the infrared energy for use as heat and chemical energy for treating the affluent waste output and converting the waste to fuel, for example, a hydrocarbon fuel.

All patents referenced herein should be deemed to be incorporated herein by reference in their entirety as to their entire subject matter. One of ordinary skill in the art should only deem the several embodiments of a solar concentrator and conversion apparatus and method described above to be limited by the scope of the claims which follow.

What we claim is:

1. Apparatus for obtaining radiant energy from a polychromatic radiant energy source, the apparatus comprising:
a concentrator for concentrating the radiant energy to a multiple of incident radiant energy;
a spectral separator for separating the concentrated radiant energy into spectral bands;
a photovoltaic device for receiving a first spectral band comprising visible light and converting the received first spectral band into electricity; and
a second device for receiving a second spectral band comprising infrared electromagnetic energy and for utilizing at least heat energy received in said infrared electromagnetic energy.

2. The apparatus of claim 1 wherein the concentrator comprises a collimator and a converging Fresnel lens, the collimator for receiving the radiant energy and focusing the energy at the converging Fresnel lens.

3. The apparatus of claim 1 wherein the concentrator comprises a collimator and a diverging Fresnel lens.

4. The apparatus of claim 1 wherein the concentrator comprises a converging Fresnel lens.

5. The apparatus of claim 1 wherein the spectral separator comprises a dichroic lens.

6. The apparatus of claim 4 wherein the dichroic lens comprises a plurality of dichroic lenses operable at different bands in the visible spectrum.

7. The apparatus of claim 1 further comprising a motor system for moving said apparatus to follow a source of electromagnetic radiation.

8. The apparatus of claim 4 further comprising an infrared Fresnel lens.

9. The apparatus of claim 1 wherein the second device includes a heat accumulator.

10. Apparatus for obtaining radiant energy from a polychromatic radiant energy source, the apparatus comprising:
a collimator concentrator for concentrating the radiant energy to a multiple of incident radiant energy;
a spectral separator for separating the concentrated radiant energy into spectral bands;
a photovoltaic device for receiving a first spectral band comprising visible light and converting the received first spectral band into electricity; and
a second device for receiving a second spectral band comprising infrared electromagnetic energy and for utilizing at least heat energy received in said infrared electromagnetic energy.

11. The apparatus of claim 10 further comprising a converging Fresnel lens for further concentrating the radiant energy.

12. The apparatus of claim 11 further wherein the spectral separator comprises a hot dichroic lens.

13. The apparatus of claim 11 wherein the spectral separator comprises a cold dichroic lens.

14. The apparatus of claim 11 comprising an array of Fresnel lens, collimator and spectral separators focusing energy at a central accumulator.

15. A method for converting solar energy to electric energy and to another form of energy comprising
collecting diffuse radiant energy using a collimator;
focusing collected energy using a Fresnel lens system;
separating the focused energy into first and second bands of radiant energy whereby one of said first and second bands comprises an infrared band and
using one of said first and second bands for generating electric energy and the other of said bands for generating the other form of energy.

16. The method of claim 15 further comprising
transforming water into molecular hydrogen and molecular oxygen.

17. The method of claim 15 further comprising
remediating a polluted stream.

18. The method of claim 15 further comprising
storing energy via producing molecular Hydrogen.

19. The method of claim 15 wherein the other form of energy is one of mechanical, chemical and thermal energy.
